(19) United States
(12) Patent Application Publication
(10) Pub. No.: US 2010/0108132 A1
(43) Pub. Date: May 6, 2010

(54) NANO-DEVICES AND METHODS OF MANUFACTURE THEREOF

(75) Inventors: Loucas Tsakalakos, Niskayuna, NY (US); Bastiaan Arie Korevaar, Schenectady, NY (US); Joleyn Eileen Balch, Schaghticoke, NY (US); Jody Fronheiser, Selkirk, NY (US); Bo Li, Clifton Park, NY (US); Anis Zribi, Colorado Springs, CO (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 12/261,171

(22) Filed: Oct. 30, 2008

(51) Int. Cl. H01L 31/0352; H01L 21/20; H01L 29/06

(52) U.S. Cl. 136/256; 257/414; 438/479; 257/415; 257/E29.022; 257/E21.09; 257/E31.032

(57) ABSTRACT

Disclosed herein is a nanodevice. Disclosed herein too is a method of manufacturing a nanodevice. In one embodiment the nanodevice includes a first substrate; a second substrate; a nanowire; the nanowire contacting the first substrate and the second substrate; the nanowire comprising a metal, a semi-conductor or a combination thereof.

### BACKGROUND OF THE INVENTION

This disclosure relates to nano-devices and to methods of manufacture thereof.

Fabrication processes for the manufacture of nano-devices involve growing nanowires on a first substrate and then transferring them to a second substrate to facilitate the manufacturing of the nano-device. Transferring methods such as drop casting of nanowires suspended in a solution, mechanical rubbing of the first substrate that contains the nanowires against the second substrate, transferring nanowires using nanomanipulation methods, and the like, have been attempted. These methods of transferring the nanowires generally have drawbacks in that there is poor control of the number of nanowires transferred and the position of the transferred nanowires on the second substrate. In addition, the transferring often causes mechanical damage to the nanowires and there is poor electrical contact between the nanowires and the second substrate. These methods are therefore not suitable for mass production.

There is therefore a need to develop new methods for the production of nano-devices. It is also desirable for these new methods to be amenable to mass production.

### BRIEF DESCRIPTION OF THE INVENTION

Disclosed herein is a nanodevice comprising a first substrate; a second substrate; and a nanowire; the nanowire contacting the first substrate and the second substrate; the nanowire comprising a metal, a semi-conductor or a combination thereof.

Disclosed herein too is a nanodevice comprising a first substrate; a second substrate; a first set of nanowires; the first set of nanowires contacting the first substrate and the second substrate; a third substrate; and a second set of nanowires; the second set of nanowires contacting the second substrate and the third substrate; wherein the first set of nanowires and the second set of nanowires comprising a semi-conductor, a metal, or a combination thereof.

Disclosed herein too is a method comprising growing upon a first substrate a nanowire; the nanowire being substantially perpendicular to the first substrate; the nanowire comprising silicon, germanium, silicon carbide, gallium arsenide, gallium nitride, gallium phosphide, indium phosphide, indium arsenide, aluminum nitride, indium oxide, indium tin oxide, tin oxide, antimony tin oxide, cadmium sulfide, or a combination comprising at least one of the foregoing materials; disposing upon the first substrate a sacrificial material; and disposing upon the sacrificial material a second substrate; the second substrate contacting the nanowire.

### BRIEF DESCRIPTION OF THE DRAWING

FIG. 1 is an exemplary depiction of a nano-device that comprises a first substrate and a second substrate with nanowires disposed therebetween;

FIG. 2 depicts one method of manufacturing the nano-device;

FIG. 3 depicts a plurality of nano-devices that can be disposed upon one another to form a stack;

FIG. 4 depicts one exemplary embodiment of a nanosensor; and

FIG. 5 is a photomicrograph of a nanodevice.

### DETAILED DESCRIPTION OF THE INVENTION

It is to be noted that as used herein, the terms “first,” “second,” and the like do not denote any order or importance, but rather are used to distinguish one element from another, and the terms “the”, “a” and “an” do not denote a limitation of quantity, but rather denote the presence of at least one of the referenced item. Furthermore, all ranges disclosed herein are inclusive of the endpoints and independently combinable.

The term nanowire as used herein encompasses objects having diameters of less than or equal to about 1,000 nanometers. They therefore encompass nanowires (e.g., semiconductors such as silicon, germanium, cadmium telluride, gallium arsenide, or the like), nanorods (e.g., those made from metals such as aluminum, copper, or the like) or ceramics (e.g., silicon dioxide, alumina, or the like), nanotubes (e.g., carbon nanotubes, molybdenum nanotubes, lead zirconate titanate nanotubes, or the like) and other nanosized objects that have diameters of less than 1,000 nanometers. Generally, nanowires are linear objects. They do not, however, always have to be linear. For example, they can be branched.

Disclosed herein is a method for manufacturing a nano-device in a manner that is amenable to mass production. The method advantageously involves growing the nanowires on a substrate in a vertical direction from the substrate. During the development of the nano-device, these nanowires are disposed upon the substrate in a vertical orientation, which allows for inherent thermal isolation of the nanowires from their neighboring nanowires. This isolation of the nanowires from their neighboring nanowires allows for the nano-device to be self-heated. In one embodiment, the nanowires can be grown in a fluidic cavity, which allows controlled flow of laminar air to the nanowires surfaces to keep them apart from one another during growth. In one exemplary embodiment, the nano-device is a nanosensor. Nano-sensors made by this method can be used for sensing liquid and gaseous chemicals and can also be used as biological sensors.

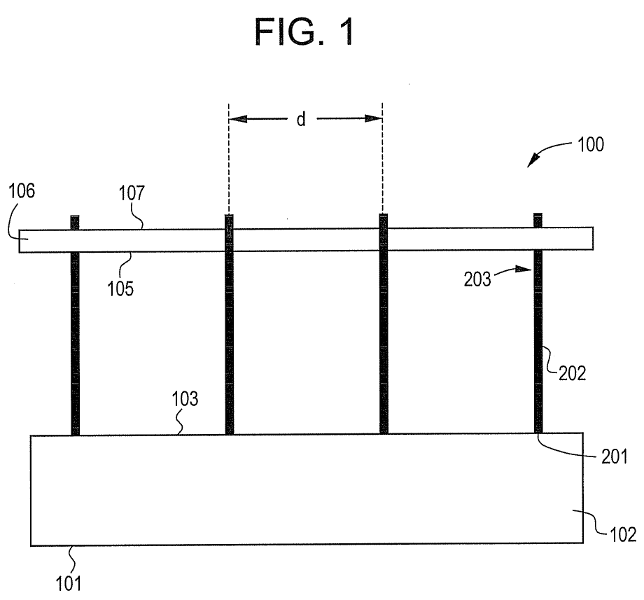

With reference now to the FIG. 1, the nano-device 100 comprises a first substrate 102 and a second substrate 106 with nanowires 202 disposed therebetween and contacting the first substrate 102 and the second substrate 106. As used herein, the terms “contacting” and “contact,” unless otherwise explicitly modified, mean to be in electrical communication with the body being contacted, and should not be understood to be limited to mean physical contact. Electrical communication (or “electrical contact”) between bodies may be achieved by several means, some of which involve physical contact, as by electrical conduction, but others of which do not involve physical contact, as by tunneling junctions or capacitive coupling.

Each substrate comprises a first face and a second face, with the first face being opposedly disposed to the second face. For example, the first substrate 102 comprises a first face 101 and a second face 103, while the second substrate 106 comprises a first face 105 and a second face 107. As can be seen in the FIG. 1, the second face 103 of the first substrate 102 is opposedly disposed to the first face 105 of the second substrate 106.

The nanowires can contact the respective substrates at an end 201 of the nanowires, along the circumferential surface 203 or at both the end 201 and the circumferential surface 203. When the nanowires contact the respective substrate at the circumferential surface 203, they can penetrate the respective substrate. For example, as can be seen in the FIG. 1, the end 201 of the nanowire 202 contacts the first substrate 102, while the circumferential surface 203 of the nanowire 202 contacts the second substrate 106. The nanowire 202 thus penetrates the second substrate 106. A single nanowire can thus penetrate two, three, four, or more substrates. In one embodiment, a single nanowire 202 can penetrate a plurality of substrates.

The nanowires 202 can be metallic or non-metallic and can display a variety of different properties. For example, they can be electrically conducting, semi-conducting, superconducting, dielectric, or the like. In one embodiment, the nanowires can comprise an electrically conducting material or a semi-conducting material. In another embodiment, the nanowires can comprise a metal.

The nanowires can be grown in a predetermined pattern or they can be grown randomly. In one embodiment, the nanowires can be functionalized to achieve a selected value of sensitivity and selectivity. While the FIG. 1 depicts single nanowires contacting the substrates, a plurality of nanowires (e.g., a cluster of nanowires) may also be used to contact the substrates at a given location.

Examples of suitable nanowires are carbon nanotubes, metallic nanorods, semiconducting nanorods, and the like. Examples of suitable metals that can be used in the nanorods are copper, aluminum, iron, steel, brass, gold, platinum, nickel, tungsten, tantalum, niobium, titanium, cobalt, molybdenum, chromium, silver or the like, or a combination comprising at least one of the foregoing metals. General examples of suitable materials that can be used in the nanowires are silicon, germanium, silicon carbide, gallium arsenide, gallium nitride, gallium phosphide, indium phosphide, indium arsenide, aluminum nitride, indium oxide, indium tin oxide, tin oxide, antimony tin oxide, tungsten oxide, aluminum oxide, silicon oxide, hafnium oxide, lead zirconate, lead zirconate titanate, cadmium sulfide, cadmium selenide, cadmium telluride, or the like, or a combination comprising at least one of the foregoing materials.

The nanowires can be multilayered. In one embodiment, the nanowires can comprise an insulating core surrounded by a layer comprising an electrically conducting or semiconducting material. In another embodiment, the nanowires can comprise a semiconducting core surrounded by a layer comprising an electrically conducting material. For example, the nanowires can comprise a silicon core surrounded by a layer of an electrically conducting material, such as, for example, tin oxide, tungsten oxide, indium tin oxide, and the like. The layer of electrically conducting material can be optically transparent or can be opaque.

The average spacing between nearest nanowires can be about 10 to about 500 nanometers. In one embodiment, the average spacing between nanowires can be about 50 to about 300 nanometers while in another embodiment it can be about 70 to about 150 nanometers. The nanowires 202 can have a diameter of about 1 nanometer to about 1000 nanometers. In one embodiment, the nanowires can have a diameter of about 5 nanometers to about 500 nanometers while in another embodiment it can be about 10 to about 200 nanometers. The nanowires 202 can have an aspect ratio that is greater than or equal to about 5. In one embodiment, the nanowires 202 can have an aspect ratio of specifically greater than or equal to about 50, while in another embodiment they can have an aspect ratio that is greater than or equal to about 100, and in yet another embodiment they can have an aspect ratio that is greater than or equal to about 150.

The distance “d” between the substrates can be selected depending upon the application. For example, it can be in the nanometer range or in the micrometer range. In one embodiment, the distance “d” between the substrates can be about 25 nanometers to about 100 micrometers. In another embodiment, the distance between the substrates can be about 30 nanometers to about 50 micrometers while in yet another embodiment it can be about 50 nanometers to about 30 micrometers, depending on the functionality of the nano-sensor. In even another embodiment the distance between the sensors is not constant and varies from one side to the other.

The first and the second substrates 102 and 106 can be manufactured from the same material as one another or can be manufactured from different materials from one another. For example the first substrate 102 can be manufactured from a first material, while the second substrate 106 can be manufactured from a second material. The substrates, like the nanowires, can be manufactured from different materials depending upon the application for which the nano-device is used. In one embodiment, the respective substrates can comprise a plurality of layers. Some of the layers may extend only over a portion of the substrate.

In one embodiment, the first substrate 102 is electrically insulating. The first substrate 102 can comprise ceramics or organic polymers. Examples of ceramics that can be used in the substrate are inorganic oxides, inorganic carbides, inorganic nitrides, inorganic hydroxides, inorganic oxides, inorganic carbonitrides, inorganic oxynitrides, inorganic borides, or inorganic borocarbides. Other suitable ceramics may include one or more metal carbides, metal nitrides, metal hydroxides, metal carbonitrides, metal oxynitrides, metal borides, or metal borocarbides. Metallic cations used in the foregoing inorganic materials can be transition metals, alkali metals, alkaline earth metals, rare earth metals, or the like. Alternatively, the substrate 102 can be electrically conducting or semiconducting.

Examples of suitable inorganic oxides include silica (SiO₂), alumina (Al₂O₃), titania (TiO₂), zirconia (ZrO₂), ceria (CeO₂), manganese oxide (MnO₂), zinc oxide (ZnO), iron oxides (e.g., FeO, β-Fe₂O₃, γ-Fe₂O₃, ε-Fe₂O₃, Fe₃O₄, or the like), calcium oxide (CaO), and manganese dioxide (MnO₂ and Mn₃O₄). Examples of suitable inorganic carbides include silicon carbide (SiC), titanium carbide (TiC), tantalum carbide (TaC), tungsten carbide (WC), hafnium carbide (HfC), or the like. Examples of suitable nitrides include silicon nitrides (Si3N4), titanium nitride (TiN), or the like. Examples of suitable borides include lanthanum boride (LaB6), chromium borides (CrB and CrB2), molybdenum borides (MoB2, Mo2B5 and MoB), tungsten boride (W2B5), or the like. An exemplary inorganic substrate is silica.

Examples of suitable organic polymers that may be used in the substrates are thermoplastics, blends of thermoplastics, thermosets, blends of thermosets, or blends of thermoplastics with thermosets. Examples of suitable thermoplastic polymers are polyacetals, polyolefins, polyacrylics, polycarbonates, polystyrenes, polyesters, polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyphthalides, polyacetals, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polysilazanes, polysiloxanes, or the like, or a combination comprising at least one of the foregoing polymers.

Examples of suitable thermosetting polymers are epoxies, phenolics, polysiloxanes, polyimides, polyacrylates, or the like, or a combination comprising at least one of the foregoing thermosets.

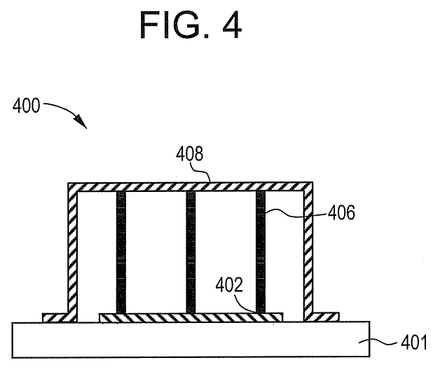

It is to be noted that an exemplary substrate comprises silica or titania. The substrates can generally have a thickness of about 50 nanometers to about 500 micrometers. In one embodiment, the substrates can have a thickness can be about 70 to about 400 nanometers while in another embodiment they can have a thickness of about 100 nanometers to about 300 nanometers. As noted above, an electrically conducting layer can be disposed upon the first substrate. This electrically conducting layer can serve as a first electrode and it is detailed in the FIG. 4. While the first electrode is depicted as contacting the first substrate in the FIG. 4, it should be noted that it does not always have to do so. In other words, the first electrode can be suspended between the first substrate and the second substrate.

The second substrate 106 can be electrically insulating or electrically conducting. In one embodiment, the second substrate 106 is electrically conducting. When the second substrate 106 is electrically conducting it can be used as a second electrode. The second substrate can be manufactured from metals, electrically conducting or semi-conducting ceramics, electrically conducting organic polymers, or combinations thereof. Examples of metals that can be used in the second substrate are iron, steel, copper, nickel, titanium, cobalt, silver, gold, platinum, palladium, or the like, or a combination comprising at least one of the foregoing metals. Examples of ceramics for use in the second substrate 106 are indium tin oxide, tungsten oxide, tin oxide, antimony tin oxide, or the like, or a combination comprising at least one of the foregoing ceramics. Examples of electrically conducting polymers are polypyrroles, polyanilines, polyacetylenes, polythiophenes, or the like, or a combination comprising at least one of the foregoing electrically conducting polymers.

While the first substrate 102 and the second substrate 106 can be seen to be substantially parallel to each other in the FIG. 1, this need not always be so. For example, the first substrate 102 can be inclined to the second substrate 106. The space between the first substrate 102 and the second substrate 106 can be filled with a gas or a liquid.

The first substrate and the second substrate can be inclined to each other such that an internal angle between a tangent to the first substrate and a tangent to the second substrate is about 1 degree to about 179 degrees. In one embodiment, the internal angle is about 5 degrees to about 90 degrees. In another embodiment, the internal angle is about 10 degrees to about 60 degrees. In one embodiment, the first substrate can be inclined to the second substrate and the first substrate can be in operative communication with the second substrate. In another embodiment, the first substrate can contact the second substrate.

The nanowires are generally perpendicular to the first substrate and/or the second substrate. In addition, it is to be noted that the nanowires can be inclined to the first and/or the second substrate. For example the nanowires can be inclined at an angle of about 1 to about 89 degrees to a normal to the first substrate and/or to a normal to the second substrate. In one embodiment, it can be inclined at an angle of about 5 to about 75 degrees to a normal to the first substrate and/or to a normal to the second substrate. In yet another embodiment, it can be inclined at an angle of about 15 to about 50 degrees to a normal to the first substrate and/or to a normal to the second substrate.

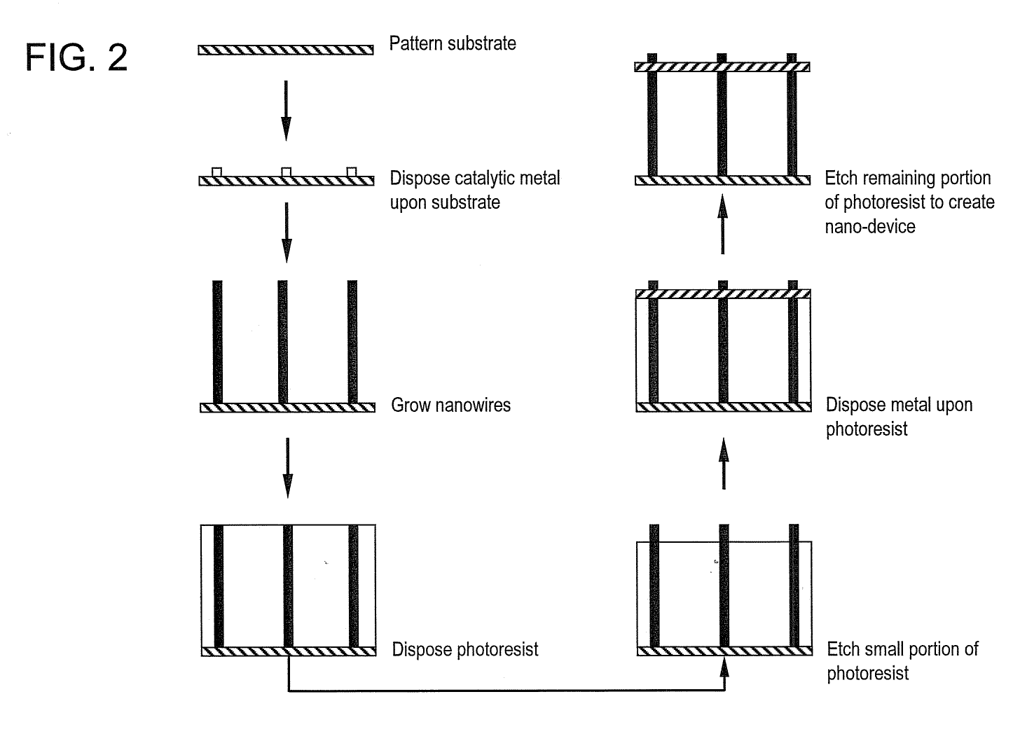

FIG. 2 depicts one method of manufacturing the nano-device. In one method of manufacturing the nano-device, a first substrate has islands of catalytic metal deposited on it. Various forms of nanolithography may be used to deposit the islands of catalytic metal at specified locations on the first substrate. Examples of nanolithography are photolithography, thermoplastic nanoimprint lithography and step-and-flash imprint lithography. Following the deposition of the catalytic metal on the first substrate, the nanowires are grown from the catalytic particles. In one embodiment, the substrate with the catalytic metal disposed thereon can be exposed to an atmosphere comprising hydrocarbons (e.g., acetylene, methane, or the like) and hydrogen at a temperature of about 500 to about 900° C. to produce carbon nanotubes from the catalytic metals. In another embodiment, the substrate with the catalytic metal disposed thereon can be exposed to an atmosphere comprising a silicon precursor (e.g., silane, dichlorosilane, or the like), hydrogen chloride, hydrogen, and a dopant precursor gas (e.g., trimethylboron or phosphine) at a temperature of about 400 to about 1000° C. to produce silicon nanowires from the catalytic metals.

In another embodiment, the nanowires can be etched into the first substrate rather than being grown from the substrate. A first substrate of suitable thickness has a photoresist disposed upon it. The portions not coated with the photoresist are then etched up to a selected depth leaving behind nanowires disposed upon a substrate.

Following the growth of the nanowires, a sacrificial material of the suitable thickness is disposed upon the substrate. The thickness of the sacrificial material determines the distance between the first and the second substrate. As can be seen in the FIG. 2, a portion of the sacrificial material is then etched away exposing a portion of the nanowires. The etching away of a portion of the sacrificial material is conducted using reactive ion etching (RIE), chemical etching, or the like.

A layer of a material is then disposed on a surface of the sacrificial material that is opposed to the surface in contact with the first substrate. The layer of material forms the second substrate. The layer of the material may be disposed on the sacrificial material by physical vapor deposition, chemical vapor deposition, sputtering, plasma enhanced vapor deposition, and the like. Following the deposition of the second substrate, the sacrificial material is etched away to produce the nano-device. As can be seen in the FIG. 2, the second substrate appears to be floating above the first substrate.

In one embodiment, the second substrate can serve as an electrode. In this event, the layer of material is electrically conducting. Examples of electrically conducting materials are provided above. In one embodiment, the second electrodes are deposited and patterned using a micromachining processes.

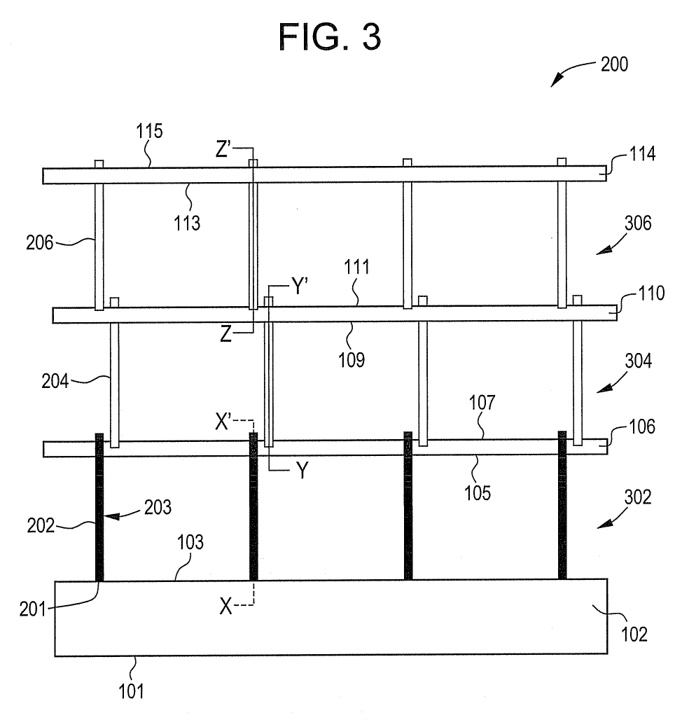

In one embodiment, a plurality of nano-devices can be disposed upon one another to form a stack 200 of nano-devices as depicted in the FIG. 3. The stack 200 of the FIG. 2 is an exemplary depiction that comprises a first nano-device 302, a second nano-device 304 and a third nano-device 306. The second nano-device 304 is disposed upon the first nano-device 302 and the third nano-device 306 is disposed upon the second nano-device.

The first nano-device 302 comprises the first substrate 102 and the second substrate 106 with a first set of nanowires being disposed therebetween and in contact with the first substrate 102 and the second substrate 106. The second nano-device 304 comprises the second substrate 106 and a third substrate 110 with a second set of nanowires 204 being disposed therebetween and in contact with the second substrate 106 and the third substrate 110. The third nano-device 306 comprises the third substrate 110 and a fourth substrate 114 with a third set of nanowires 206 being disposed therebetween and in contact with the third substrate 110 and the fourth substrate. In the embodiment depicted in the FIG. 3, the longitudinal axes XX′ to the first set of nanowires 202, the longitudinal axes YY′ to the second set of nanowires 204 and the longitudinal axes ZZ′ to the third set of nanowires 206 are offset from each other.

In another embodiment, the longitudinal axes XX′ to the first set of nanowires 202, the longitudinal axes YY′ to the second set of nanowires 204 and the longitudinal axes ZZ′ to the third set of nanowires 206 can be aligned along a single vertical line. This is not depicted in the FIG. 3. All these wires can potentially be of the same material, but also of different materials.

In the FIG. 3, the third substrate 110 is disposed upon the second substrate 106 and the fourth substrate 114 is disposed upon the third substrate 110. The third substrate 110 has a first face 109 and a second face 111, with the first face 109 being opposedly disposed to the second face 111. Likewise, the fourth substrate 114 has a first face 113 and a second face 115, with the first face 113 being opposedly disposed to the second face 115. As can be seen in the FIG. 3, a second set of nanowires 204 are disposed upon the second face 107 of the second substrate 106, while a third set of nanowires 206 are disposed upon the second face 111 of the third substrate 110. The second set of nanowires 204 contacts the third substrate 110 while the third set of nanowires 206 contacts the fourth substrate 114.

The first set of nanowires 202, the second set of nanowires 204 and the third set of nanowires 206 can have similar or different chemical compositions from each other. In one embodiment, the first set of nanowires are the same as the second set of nanowires and the third set of nanowires. In other words, the first set of nanowires contacts the first substrate 102, the second substrate 106 and the third substrate 110. In another embodiment, the first substrate 102, the second substrate 106, the third substrate 110 and the fourth substrate 114 can have similar or different chemical compositions from each other. Each, some or all of the foregoing substrates can be multi-layered.

The stack of nano-devices can be used to make a multitude of different measurements. For example, the first nano-device can be used as a sensor for carbon dioxide, while the second nano-device can be used as a sensor for carbon monoxide, and the third sensor can be used as a sensor for nitrogen oxides.

In one embodiment, the method described herein can be used to manufacture a gas nanosensor. The FIG. 4 depicts one exemplary embodiment of the nanosensor 400, which comprises a substrate 401 upon which is deposed a first electrode 402. In that case, the substrate is an electrically insulating material. The first electrode 402 is patterned as described above to grow the nanowires 404. In one embodiment related to the growth of the nanowires, the nanowires may be grown in a fluidic cavity to allow controlled (laminar) air flow to the nanowire surfaces. Multiple nanowires of varying density can be grown to control the sensitivity and dynamic range of the sensor.

After growing the nanowires 404, a sacrificial material is disposed on the surface of the first electrode 402 (not shown). The sacrificial material stabilizes the nanowires 404 during the deposition of the second electrode 408. Following the deposition of the second electrode 408, the sacrificial material is removed leaving behind nanowires whose opposing ends contact the first electrode 402 and the second electrode 408.

The substrate 401 that is employed in the nanosensor 400 can be specific to the nanowires used in the device. For example, if the nanosensor uses tin oxide nanowires, the substrate will be a titania substrate, which is not electrically conductive. In this case, a metal layer 402 can be deposited around the nanowires after growth, and then etched back leaving a thin bottom contact. The metal layer acts as the first electrode 402. A metal layer comprising the same or a different metal can be used as the second electrode 408. A similar etch back process (as described above) can be used to fabricate the second electrode 408 and contact the nanowires as shown in the FIG. 4.

In another embodiment, silicon nanowires can be grown on a degenerately doped silicon substrate, and then coated with a thin gas-sensitive polycrystalline metal oxide film such as tin oxide. The tin oxide acts as an electrode and forms the first electrode 402. The second electrode 408 is then fashioned using the sacrificial material etch back process and metal deposition processes described above. Temperature probes (not shown) can also be micro-fabricated directly on the substrates to allow for temperature monitoring and feedback to control the local temperature of the nanowires for optimized sensor performance.

As can be seen, the fabrication process for the gas nanosensor does not use a nanowire transferring process from a nanowire growth substrate to the device substrate. The nanowires are instead directly grown on the same substrate where nanosensors are built. In one embodiment, the catalysts for nanowire growth are patterned so that the number of nanowires in each device can be used as a design parameter to achieve optimum device performance.

The present design of the nanosensor allows the nanowires to be open to analytes for sensing applications. This structure is applicable to both chemical/gas and biological sensing applications. The design of the nanosensor also allows the nanowire sensor to be operated in a self-heating mode. By applying an electrical current through the nanowires, the nanowires can be heated up to a suitable temperature to achieve a chosen sensing performance. For example, metal oxide nanowires can be heated up to an elevated temperature to obtain better sensitivity and fast recovery. The structure of the nanosensor can obviate the use of an additional heating element and as a result consume much less power.

This bottom-up approach of building a nanosensor avoids the nanowire transferring process, which is currently a bottleneck for nanowire devices in general. It is suitable for mass fabrication of nanowire-based devices with low cost and high yield. In addition, it provides better electrical contact between electrodes and the nanowires, which is also a major problem for current nanowire devices. At the same time, the mechanical strength of the contact should also be superior than devices built using a top down approach. The nanodevice can be used as a gas sensor, a solar cell, or the like.

The following example illustrates methods and embodiments in accordance with the invention, and as such should not be construed as imposing limitations upon the claims. These examples demonstrate the manufacture of the nano-devices described herein and demonstrate their performance compared with other nano-devices that are commercially available.

### EXAMPLE

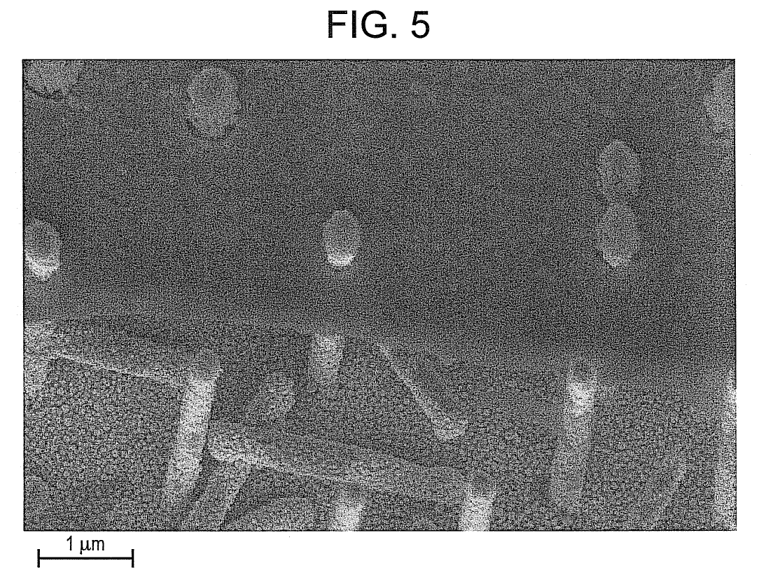

This example was conducted to demonstrate a method for manufacturing the nano-device disclosed herein. A <111> silicon wafer was used as the substrate. A pattern of 0.7 to 0.8 micrometer diameter gold catalyst dots was disposed on the substrate using photolithography. The gold catalyst was 5 nm thick and was deposited by electron beam evaporation onto a double layer liftoff photoresist structure. The liftoff was performed in standard resist solvents (acetone and N-methyl pyrrolidone based solvents). Silicon nanowires having a length of approximately 3 micrometers were grown perpendicular to the <111> silicon wafer surface using thermal chemical vapor deposition. The wires were then coated with amorphous silicon and indium tin oxide (ITO), giving the nanowires a rough grain structure observed in the SEM image shown in the FIG. 5.

A □micrometer thick layer of photoresist was spin coated onto the substrate containing the nanowire array, filling in the gaps between wires and forming a nearly planar layer of photoresist around and above the nanowire arrays. A nearly isotropic photoresist etch was performed in an Anelva reactive ion etch (RIE) system using an oxygen based chemistry. The etch conditions were 100 standard cubic centimeters (sccm) O2 flow at 100 millitorr (mTorr) and 400 watts (W). The resist was etched back far enough to expose the top 1 micrometer lengths of the silicon nanowires leaving a planar photoresist film between the extending nanowire tips. A 2-micrometer thick aluminum metal layer was then deposited on this structure by e-beam evaporation through a shadow mask used to define device regions. The photoresist acts as a platform on which a metal film can be formed so that when the photoresist is removed with solvents after metal deposition, a “floating” metal film is left, supported by nanowire posts.

While the invention has been described in detail in connection with a number of embodiments, the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. A nanodevice comprising:
a first substrate;
a second substrate; and
a nanowire; the nanowire arranged to penetrate at least one of the first substrate and the second substrate; the nanowire comprising a metal, a semi-conductor or a combination thereof.

2. The nanodevice of claim 1, wherein the first substrate contacts the second substrate; and wherein the angle between the first substrate and the second substrate is about 1 degree to about 179 degrees.

3. The nanodevice of claim 1, wherein the nanowire is inclined at an angle of about 1 to about 89 degrees with a normal to the first substrate and/or the second substrate.

4. The nanodevice of claim 1, wherein a space between the first substrate and the second substrate is accessible to a gaseous or liquid phase.

5. The nanodevice of claim 1, further comprising a first electrode; the first electrode being electrically conducting and being in electrical contact with the nanowire.

6. The nanodevice of claim 5, wherein the first electrode contacts the first substrate.

7. The nanodevice of claim 1, where the second substrate is electrically conducting.

8. The nanodevice of claim 1, where the second substrate functions as an electrode.

9. The nanodevice of claim 1, wherein the first substrate comprises silica or titania.

10. The nanodevice of claim 1, wherein the nanowire is multilayered.

11. The nanodevice of claim 1, wherein the nanowire comprises a silica core surrounded by a layer of indium tin oxide or tin oxide.

12. The nanodevice of claim 11, wherein the nanowire is coated with an electrically conducting material.

13. The nanodevice of claim 12, wherein the electrically conducting material is optically transparent.

14. The nanodevice of claim 5, wherein the second substrate comprises aluminum.

15. The nanodevice of claim 1, wherein the nanowires comprise silicon, germanium, silicon carbide, gallium arsenide, gallium nitride, gallium phosphide, indium phosphide, indium arsenide, aluminum nitride, indium oxide, indium tin oxide, tin oxide, antimony tin oxide, tungsten oxide, aluminum oxide, silicon oxide, hafnium oxide, lead zirconate, lead zirconate titanate, cadmium sulfide, cadmium selenide, cadmium telluride, or a combination comprising at least one of the foregoing materials.

16. The nanodevice of claim 1, wherein the nanowires comprise copper, aluminum, iron, steel, brass, gold, platinum, nickel, tungsten, tantalum, niobium, titanium, cobalt, molybdenum, chromium, silver or a combination comprising at least one of the foregoing materials.

17. An article comprising the nanodevice of claim 1.

18. An article comprising the nanodevice of claim 2.

19. The nanodevice of claim 15, wherein the nanodevice is a gas sensor, a solar cell or a mechanical sensor.

20. An article comprising a plurality of nanodevices of claim 1, the nanodevices being stacked atop one another.

21. A nanodevice comprising:
a first substrate;
a second substrate;
a first set of nanowires; the first set of nanowires arranged to penetrate at least one of the first substrate and the second substrate;
a third substrate; and
a second set of nanowires; the second set of nanowires arranged to penetrate at least one of the second substrate and the third substrate; wherein the first set of nanowires and the second set of nanowires comprising a semi-conductor, a metal, or a combination thereof.

22. The nanodevice of claim 21, where the nanowires are electrically conducting, semi-conducting, superconducting, or dielectric.

23. The nanodevice of claim 21, further comprising a fourth substrate and a third set of nanowires; the fourth set of nanowires contacting the third substrate and the fourth substrate.

24. The nanodevice of claim 21, wherein the first substrate, the second substrate and/or the third substrate are electrically conducting.

25. The nanodevice of claim 21, wherein the first substrate, the second substrate and/or the third substrate are multi-layered.

26. The nanodevice of claim 23, wherein the first substrate, the second substrate, the third substrate and the fourth substrate each comprises a material having a different chemical composition.

27. The nanodevice of claim 23, wherein the first set of nanowires, the second set of nanowires and the third set of nanowires each comprises a material having a different chemical composition.

28. The nanodevice of claim 21, wherein the first set of nanowires is the same as the second set of nanowires.

29-40. (canceled)

41. The nanodevice of claim 1, wherein the nanowire is arranged to penetrate a portion of a respective thickness of at least one of the first substrate and the second substrate.

42. The nanodevice of claim 1, wherein the nanowire is arranged to penetrate an entire thickness of at least one of the first substrate and the second substrate.

43. The nanodevice of claim 21, wherein the first set of nanowires is arranged to penetrate a portion of a respective thickness of at least one of the first substrate and the second substrate.

44. The nanodevice of claim 21, wherein the first set of nanowires is arranged to penetrate an entire thickness of at least one of the first substrate and the second substrate.

45. The nanodevice of claim 21, wherein the second set of nanowires is arranged to penetrate a portion of a respective thickness of at least one of the second substrate and the third substrate.

46. The nanodevice of claim 21, wherein the second set of nanowires is arranged to penetrate an entire thickness of at least one of the second substrate and the third substrate.
